(19) United States
(12) Patent Application Publication
(10) Pub. No.: US 2001/0054889 A1
(43) Pub. Date: Dec. 27, 2001

(54) METHOD OF ANALYZING THE SPECTRUM OF A RADIO COMMUNICATION SYSTEM TRANSMISSION SIGNAL

(76) Inventor: OLIVIER DANET, OSYNY (FR)

Correspondence Address: SUGHRUE MION ZINN MACPEAK & SEAS PLLC, 2100 PENNSYLVANIA AVE NW, STE 800, WASHINGTON, DC, 200373213

(21) Appl. No.: 09/382,696

(22) Filed: Aug. 25, 1999

(30) Foreign Application Priority Data
Aug. 27, 1998 (FR) 98 10 761

(51) Int. Cl. G01R 23/165

(52) U.S. Cl. 324/76.29

(57) ABSTRACT

In a method of analyzing the spectrum of a radio communication system transmission signal having a given carrier frequency, the transmission signal is split to obtain first and second intermediate signals. A phase-shift at the given carrier frequency is applied to at least one of the intermediate signals so that at that frequency the intermediate signals have a relative phase difference of 180°. The phase-shifted intermediate signals are recombined to form a recombined signal in which the signal part transmitted at the given carrier frequency is rejected and the spectrum of the recombined signal is analyzed.

### BACKGROUND OF THE INVENTION

1. Field of the Invention

The invention concerns a method of and a system for analyzing the spectrum of a radio communication system.

The invention applies more particularly, although not exclusively, to mobile terminals of any mobile radio network, in particular of the GSM (Global System for Mobile communications), DCS (Digital Communication System), PCS (Personal Communication Service) or DECT (Digital European Cordless Telephone) type.

2. Description of the Prior Art

Analyzing the spectrum of the signal transmitted by a mobile terminal is part of one step of testing a mobile terminal before it is put into circulation.

This step consists in verifying that frequencies other than the carrier frequency are transmitted at a power level below a particular threshold in order to prevent the transmission of interference.

To perform this step, it is indispensable to reject the carrier frequency, which would otherwise lead to saturation of the spectrum analyzer, given its configuration for the test phase.

By “carrier frequency” is meant the frequency of the payload signal.

In the prior art, the filter is used to reject the carrier frequency. The filter has the disadvantage of mismatching the signal transmission line and it is therefore essential to couple it to an attenuator.

However, the attenuation is applied to all of the signal. The parts of the signal whose frequencies must be analyzed are therefore also attenuated.

Also, outside a particular range of frequencies (10 MHz-1 GHz), transmission losses are very high and degrade the accuracy of the measurement. Accordingly, for frequencies outside this range, a different circuit is necessary: a high-pass filter must be substituted for the combination of the rejector filter and attenuator.

The invention therefore aims to provide a method of the aforementioned type that is simple to implement and gives a precise result for any type of transmission signal transmitted in a wide band of frequencies.

### SUMMARY OF THE INVENTION

To this end, the invention proposes a method of analyzing the spectrum of a radio communication system transmission signal having a given carrier frequency, wherein:

the transmission signal is split to obtain first and second intermediate signals;

a phase-shift at the given carrier frequency is applied to at least one of the intermediate signals so that at that frequency the intermediate signals have a relative phase difference of 180°;

the phase-shifted intermediate signals are recombined to form a recombined signal in which the signal part transmitted at the given carrier frequency is rejected; and

the spectrum of the recombined signal is analyzed.

A device is also proposed for analyzing the spectrum of a radio communication system transmission signal having a given carrier frequency.

This device includes a circuit receiving the transmission signal at its input and adapted to reject in the transmission signal the signal part which is transmitted at the carrier frequency, the circuit including:

splitter means for splitting the transmission signal into two intermediate signals;

phase-shifter means for applying a phase-shift to at least one of the intermediate signals at the carrier frequency so that at that frequency the intermediate signals have a relative phase difference of 180°; and

recombining means for recombining the two phase-shifted intermediate signals to form a recombined signal in which the signal part at the carrier frequency is rejected;

the recombination means being connected to the splitter means by two transmission channels each carrying one intermediate signal.

The circuit further includes a spectrum analyzer connected to the circuit to receive the recombined signal to be analyzed.

In the remainder of the text, the expression “transmission signal” means any signal transmitted or received by the radio communication system.

The invention will be better understood in the light of the following detailed description, which is given with reference to the accompanying drawings.

### BRIEF DESCRIPTION OF THE DRAWINGS

FIG. 1 is the block diagram of a first embodiment of a rejector circuit of the invention, in which phase-shifter means are provided on only one transmission channel.

FIG. 2 is a detailed schematic of a first variant of FIG. 1.

FIG. 3 is a simplified schematic of a second variant of FIG. 1.

FIG. 4 is a detailed schematic of a second embodiment of a rejector circuit of the invention in which there are phase-shifter means on two transmission channels.

FIG. 5 is a detailed schematic of a device of the invention including a variant of the rejector circuit from FIG. 4.

FIG. 6 shows a curve S_{R} representing the ratio (in dB) between the transmission signal S and the recombined signal S′ over a frequency band from 5 MHz to 2 GHz.

FIG. 7 shows the curve S_{R} from FIG. 6 over a smaller frequency band from 847.4 MHz to 957.4 MHz and a curve Sₚ representing the mismatch loss.

### DETAILED DESCRIPTION OF THE PREFERRED EMBODIMENT

There is described below a rejector circuit 1 fed at its input I with a radio communication system transmission signal S.

The radio communication system includes a mobile terminal of any radio communication network, in particular of the GSM, DCS, PCS or other type.

In other embodiments, the transmission signal may belong to other radio communication systems.

The rejector circuit 1 is adapted to produce at its output O a recombined signal S′ corresponding to the transmission signal S in which a portion S_{d} of the signal transmitted at a given frequency f_{d} has been rejected.

In the remainder of the text, the expression “upstream end” means the end at which the signal enters and the expression “downstream end” means the end at which the signal leaves.

The rejector circuit 1 includes splitter means 2 adapted to split the transmission signal S into two intermediate signals S₁ and S₂.

In the embodiments shown, the splitter means 2 comprise a Wilkinson splitter dividing the transmission signal S into two substantially equal intermediate signals.

It is to be understood that other splitters exercising the same functions as the aforementioned splitter can be used.

Splitter means 2 can also be considered that split the transmission signal S into two non-equal intermediate signals S₁ and S₂, i.e. signals having different power levels and therefore different amplitudes.

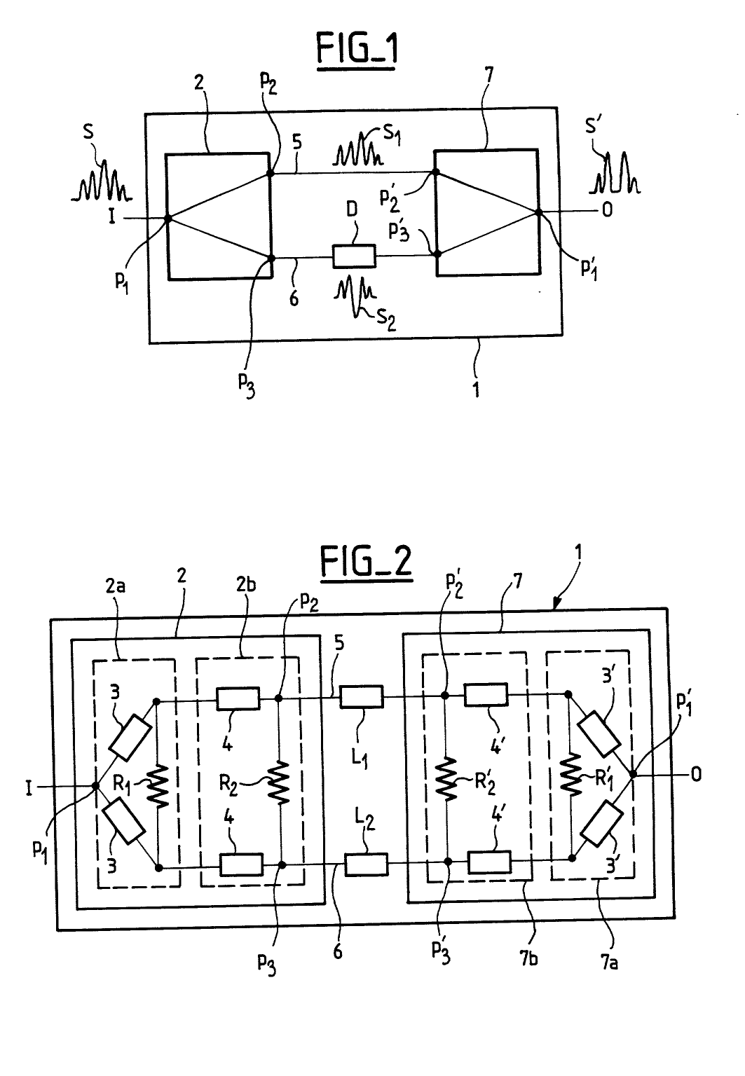

In the embodiment shown in FIGS. 1 to 5, the splitter means 2 have two parts 2a, 2b. The function of the first part 2a is to split the transmission signal S. The second part 2b also has an impedance conversion function.

The splitter means 2 produce two intermediate signals S₁ and S₂ whose power level is substantially equal to half that of the transmission signal S.

To increase the capacities of the rejector circuit 1, it is beneficial to increase the bandwidth of the splitter means 2, which can be achieved by cascading at least one impedance converter of the type included in the second part 2b.

As shown in FIG. 2 in particular, the first part 2a includes two first transmission lines 3 of substantially identical length and characteristic impedance and a first resistor R₁.

At their upstream end, the first transmission lines 3 are connected by a common point p₁ to the input I of the rejector circuit 1.

At their other end, they are connected together by the first resistor R₁, which has a power isolation function in particular.

The second part 2b includes two second transmission lines 4 of substantially identical length and characteristic impedance and a second resistor R₂.

Each first transmission line 3 is connected in series with a second transmission line 4.

The upstream ends of the second transmission lines 4 are connected together by the first resistor R₁ and their downstream ends are connected together by the second resistor R₂.

In the embodiment shown, the transmission lines 3 and 4 have the same length, which is in the order of one quarter of the wavelength of the transmission signal S.

On the other hand, the characteristic impedance of the first transmission lines 3 is preferably different to that of the second transmission lines 4.

The splitter means 2 have an input, in the form of the common point p₁, and two outputs, in the form of common points p₂, p₃ connecting the downstream end of a second transmission line 4 to the second resistor R₂.

Each common point p₂, p₃ is connected to a transmission channel 5, 6.

The transmission channels carry respective intermediate signals S₁, S₂.

The second resistor R₂ of the splitter means 2 has in particular the function of power-isolating the two transmission channels 5, 6 relative to each other.

In the embodiment shown in FIG. 2, each transmission channel 5, 6 includes a respective transmission line L₁, L₂.

The lines L₁ and L₂ each have a characteristic impedance in the order of 50 ohms.

Also, one line L₁ has a length l which is a function of the carrier frequency f₀ of the transmission signal S. The other line L₂ has a length equal to (l+λ_{d}/2) where λ_{d} is the wavelength of the transmission signal S at the given frequency f_{d}.

The characteristics of the line L₂ therefore apply a phase-shift of 180° on the transmission channel 6. The line L₂ configured in this way forms the phase-shifter means D shown in FIG. 1.

Of course, in a variant, the phase-shifter means D can be on the other transmission channel 5.

It is equally feasible for the transmission channel 5 not to include any transmission line and for the transmission channel 6 to include a transmission line whose length is a function of the given frequency f_{d} and provides the phase-shift of 180° between the two transmission channels.

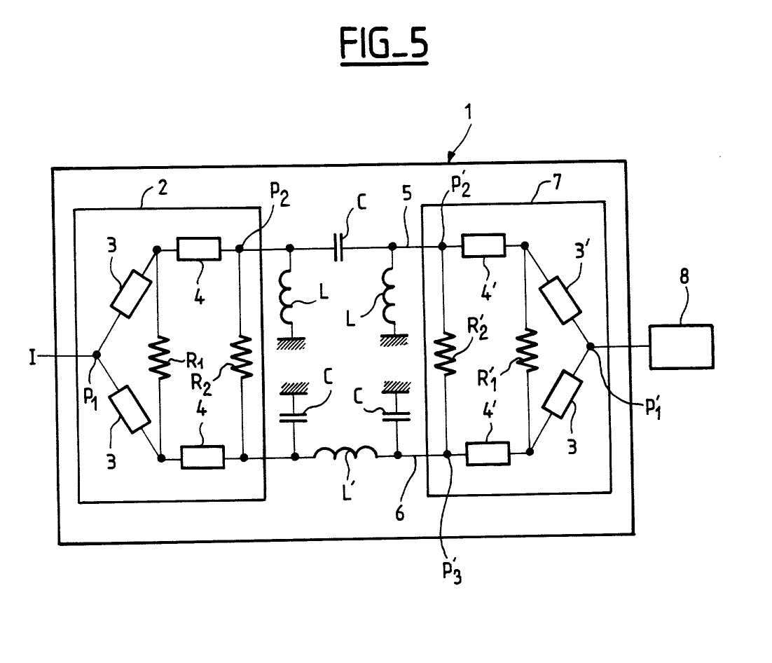

In the embodiment shown in FIG. 5, the transmission channel 5 includes a low-pass circuit LC adapted to shift the phase of the intermediate frequency S₁ by −90° at the given frequency f_{d}. Also, the transmission channel 6 includes a high-pass circuit L′C′ adapted to shift the phase of the intermediate signal S₂ by +90° at the given frequency f_{d}.

Accordingly, at the given frequency f_{d}, there is a relative phase difference of 180° between the intermediate signal S₂ on the transmission channel 6 and the intermediate signal S₁ on the transmission channel 5.

It is to be understood that, in a different embodiment using discrete components, only the intermediate signal S₁, S₂ of one of the transmission channels 5, 6 can be phase-shifted 180°, the intermediate signal S₂, S₁ of the other transmission channel 6, 5 remaining unchanged. The components of the transmission channel, and the combination thereof, will then be adapted accordingly.

Clearly, then, the phase-shifter means D can include either at least one transmission line or discrete components, the characteristics of which are a function of the given frequency f_{d}.

At their downstream end, the two transmission channels 5, 6 are connected to recombination means 7.

The function of the recombination means 7 is to recombine the two intermediate signals S₁ and S₂ to form a recombined signal S′.

Recombining the two intermediate signals S₁ and S₂ with a relative phase difference of 180° at the given frequency f_{d} substantially cancels the amplitude of the signal part S_{d} at the given frequency f_{d}.

In the embodiments shown, the recombination means 7 are substantially identical in structural terms to the splitter means 2. This makes it easier to match the recombination means 7 to the splitter means 2, regardless of their type.

The recombination means are such that the transmission signal S is reconstituted, the signal part S_{d} being rejected.

In these embodiments, the downstream end of each transmission channel 5, 6 forms an input of the recombination means 7.

The recombination means 7 have two portions 7a, 7b. The function of the first portion 7a is to recombine the two intermediate signals S₁ and S₂ after the second portion 7b has performed the impedance conversion.

As with the splitter means 2, at least one additional impedance converter of the same type can be cascaded downstream of the second portion 7b.

As can be seen in FIG. 2 in particular, the second portion 7a includes two first transmission lines 3′ of substantially identical length and characteristic impedance and a first resistor R₁′.

At their downstream end, the first transmission lines 3′ are connected by a common point p₁′ to the output O of the rejector circuit 1.

At their upstream end they are connected together by the first resistor R₁′.

The second portion 7b includes two second transmission lines 4′ of substantially identical length and characteristic impedance and a second resistor R₂′.

Each first transmission line 3′ is connected in series with a second transmission line 4′.

The downstream ends of the second transmission lines 4′ are connected together by the first resistor R₁′ and their upstream ends are connected together by the second resistor R₂′.

In the embodiment shown, the transmission lines 3′ and 4′ are the same length, in the order of one quarter of the wavelength of the transmission signal S.

On the other hand, the characteristic impedance of the first transmission lines 3′ is preferably different to that of the second transmission lines 4′.

In the present embodiments, the transmission lines 3 and 4 of the splitter means 2 are substantially identical to the transmission lines 3′ and 4′, respectively, on the recombination means 7. Likewise the resistors R₁, R₂ and R₁′, R₂′.

The upstream end of each second transmission line 4′ forms with a respective end of the second resistor R₂′ a respective common point p₂′, p₃′.

Each common point p₂′ and p₃′ is connected to a transmission channel 5, 6 and thus forms an input of the recombination means 7.

FIG. 1 is a diagrammatic representation of the signal curves at each step of the rejection process.

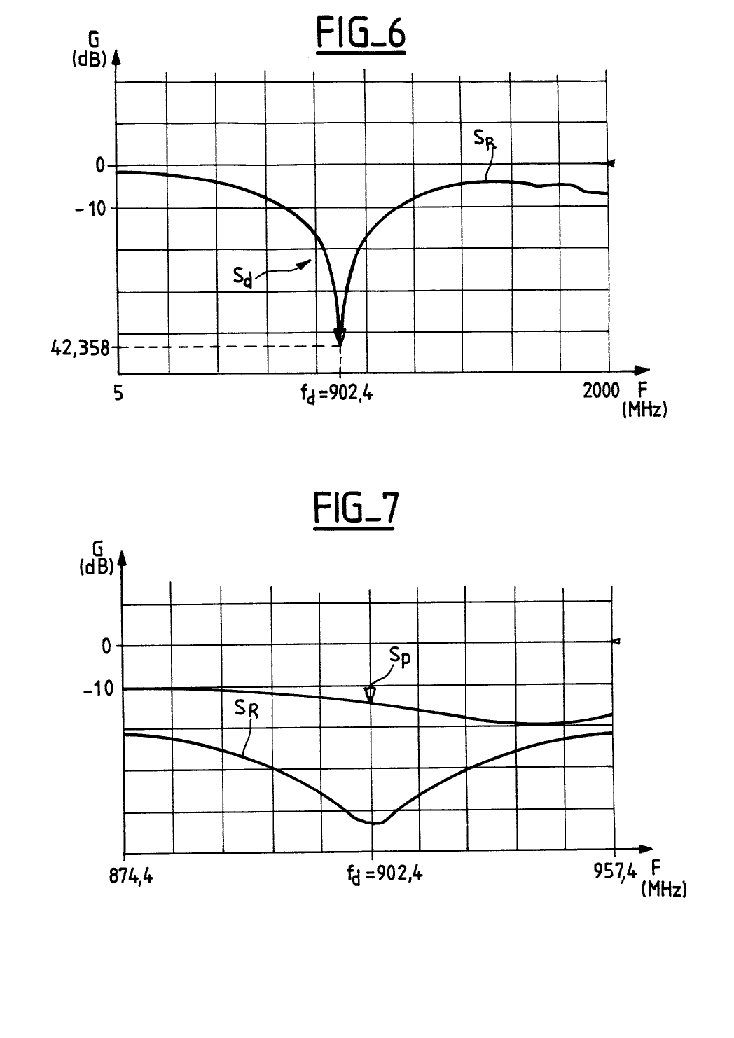

FIG. 6 also shows the ratio between the recombined signal S′ and the transmission signal S. The given frequency f_{d}, at which the corresponding signal part S_{d} is rejected, is 902.4 MHz.

FIG. 7 shows the same curve S_{R} over a smaller frequency band and the mismatch loss curve Sₚ.

Note that the power loss by reflection is small in comparison with that generated in conventional rejector circuits, which are generally highly mismatched. The analysis of the spectrum can therefore be more realistic.

This is because the circuit 1 remains matched to a characteristic impedance which is substantially constant as a function of frequency between the input I and output O.

The rejector circuit 1 is used in the context of testing a mobile terminal (not shown) adapted to operate in a particular radio communication network.

One step of the test analyzes the spectrum of the signal transmitted by the mobile terminal.

The output of the transmitter of the mobile terminal is then connected to the input I of the rejector circuit 1 and the input of a spectrum analyzer 8 is connected to the output O of the rejector circuit 1 (FIG. 5).

Under these conditions, the spectrum analyzer 8 must verify that the frequencies other than the carrier frequency f₀ of the transmission signal S from the mobile terminal are transmitted at a sufficiently low power level.

It is therefore necessary to reject the transmitted signal part at the carrier frequency f₀ of the transmission signal S, i.e. the payload signal.

The given frequency f_{d}, used in the rejector circuit 1, is then equal to the carrier frequency f₀ of the transmission signal S, i.e. the frequency of the payload signal.

The analyzer 8 then analyzes the spectrum of the recombined signal S′ from which the payload signal has been rejected.

Also, the rejector circuit 1 is configured as a function of the given frequency.

The rejector circuit 1 can equally be used in the context of the operation of a mobile terminal in a particular radio communication network, authorizing transmission and reception of signals, respectively, in a particular frequency band.

The rejector circuit 1 rejects a transmitted signal part at an interference frequency which here corresponds to the given frequency f_{d}.

Assuming that the interference frequency differs from one mobile terminal to another, variable frequency phase-shifter means D are used, operating as a function of the given frequency f_{d}.

Accordingly, whether they are on a single transmission channel 5, 6 or on both channels, the phase-shifter means D are adapted to adjust themselves to the interference frequency of the mobile terminal concerned.

It is to be understood that the variable frequency phase-shifter means D can also be used in the spectrum analyzer system that has just been described. They are beneficial if the payload signal frequency varies, for example.

FIG. 4 shows one embodiment of the rejector circuit 1 including variable frequency phase-shifter means on the two transmission channels 5, 6.

The rejector circuit 1 corresponds substantially to the rejector circuit from FIG. 5, but the inductors L, L′ and the capacitors C, C′ of the low-pass and high-pass circuits have been replaced by the variable inductors L₁, L₁′ and the variable capacitors C₁, C₁′, respectively.

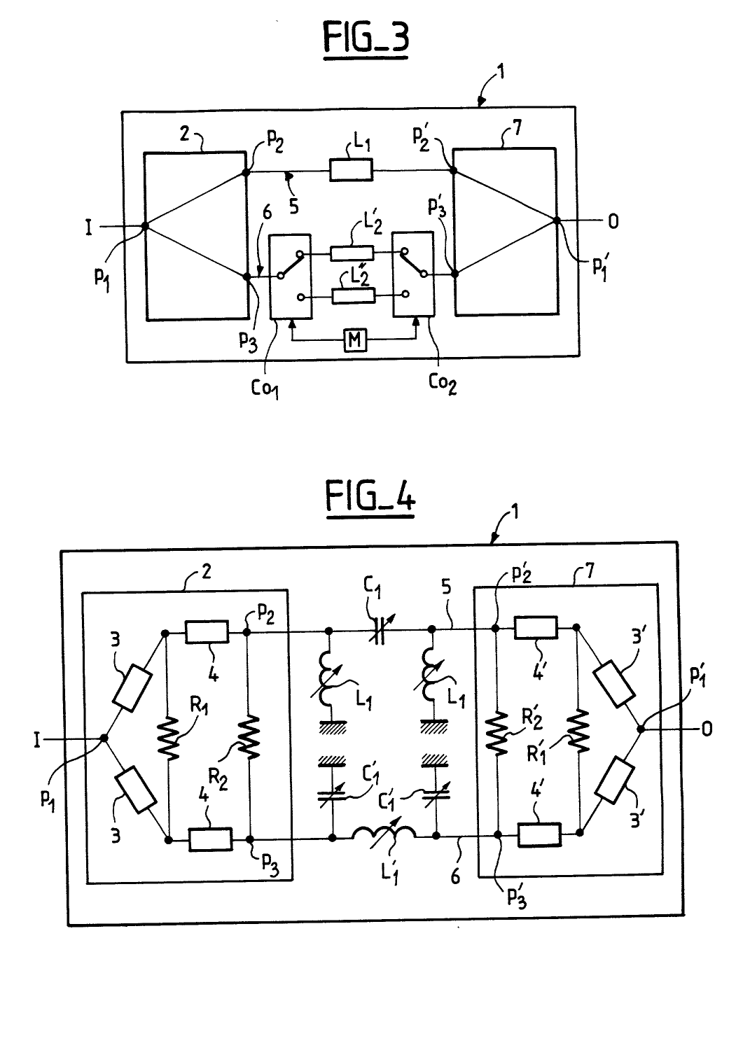

FIG. 3 shows another embodiment of a rejector circuit 1 including variable frequency phase-shifter means D on a single transmission channel 6.

The rejector circuit 1 corresponds substantially to that from FIG. 2, but the transmission line L₂ has been eliminated and replaced by two transmission lines L₂′ and L₂″ connected to opposite sides of a first switch Co₁ and a second switch Co₂.

The first switch Co₁ is connected to the common point p₃ and the second switch Co₂ is connected to the common point p₃′.

The switches Co₁ and Co₂ are adapted to make the connection between the splitter means 2 and the recombination means 7 via one or other of the transmission lines L₂′ or L₂″.

Control means M operate the switches Co₁ and Co₂ simultaneously.

It is to be understood that in the variants of FIGS. 3 and 4 the splitter means 2 and the recombination means 7 can be different to those of the embodiments previously described.

The rejector circuits 1 including variable frequency phase-shifter means D can also be used in the context of the operation of a mobile terminal adapted to operate alternately in two radio communication networks with authorized frequencies in two separate bands.

For example, in the case of a mobile terminal adapted to operate in GSM (900 MHz band) and DCS (1 800 MHz band) networks, and using a single frequency synthesizer, it will therefore be necessary to eliminate the signal part including the carrier frequency of the band of the network to be left, so as to authorize only the frequencies of the band of the other network.

The rejector circuit 1 is then connected to the output of the synthesizer and adapted to suit the given frequencies to be rejected.

There is claimed:

1. A method of analyzing the spectrum of a radio communication system transmission signal having a given carrier frequency, wherein:
said transmission signal is split to obtain first and second intermediate signals;
a phase-shift at said given carrier frequency is applied to at least one of said intermediate signals so that at that frequency said intermediate signals have a relative phase difference of 180°;
the phase-shifted intermediate signals are recombined to form a recombined signal in which the signal part transmitted at said given carrier frequency is rejected; and
the spectrum of the recombined signal is analyzed.

2. The method claimed in claim 1 wherein said transmission signal is split into two substantially equal intermediate signals.

3. The method claimed in claim 1 wherein only one of said intermediate signals is phase-shifted 180°.

4. A device for analyzing the spectrum of a radio communication system transmission signal having a given carrier frequency, including:
a circuit receiving at its input said transmission signal and adapted to reject in said transmission signal the signal part which is transmitted at said carrier frequency, said circuit including
splitter means for splitting said transmission signal into two intermediate signals;
phase-shifter means for applying a phase-shift to at least one of said intermediate signals at said carrier frequency so that at that frequency said intermediate signals have a relative phase difference of 180°; and
recombining means for recombining the two phase-shifted intermediate signals to form a recombined signal in which said signal part at said carrier frequency is rejected;
said recombination means being connected to said splitter means by two transmission channels each carrying one intermediate signal; and
a spectrum analyzer connected to said circuit to receive said recombined signal to be analyzed.

5. The system claimed in claim 4 wherein said splitter means include a splitter adapted to divide said transmission signal into two substantially equal intermediate signals.

6. The system claimed in claim 4 wherein said phase-shifter means are mounted on at least one of said transmission channels.

7. The system claimed in claim 6 wherein said phase-shifter means comprise at least one transmission line having a length which is a function of said carrier frequency.

8. The system claimed in claim 6 wherein one of said transmission channels includes a low-pass circuit adapted to shift the phase of the corresponding intermediate signal at said carrier frequency by −90° and the other transmission channel includes a high-pass circuit adapted to shift the phase of the corresponding intermediate signal at said carrier frequency by +90°.

9. The system claimed in claim 4 wherein said phase-shifter means are variable frequency phase-shifter means.

10. The system claimed in claim 4 wherein, between its input and its output, said circuit is matched to a characteristic impedance which is substantially constant as a function of frequency.
